(19) United States
(12) Patent Application Publication
(10) Pub. No.: US 2011/0156108 A1
(43) Pub. Date: Jun. 30, 2011

(54) SEMICONDUCTOR DEVICE AND METHOD OF MANUFACTURING THE SAME

(75) Inventor: Satoru MURAMATSU, Kanagawa (JP)

(73) Assignee: RENESAS ELECTRONICS CORPORATION, Kanagawa (JP)

(21) Appl. No.: 12/978,889

(22) Filed: Dec. 27, 2010

(30) Foreign Application Priority Data
Dec. 28, 2009 (JP) 2009-297252

(51) Int. Cl. H01L 29/78

(52) U.S. Cl. 257/288; 257/E29.255

(57) ABSTRACT

An insulating cover film is formed over at least a portion of a gate electrode in the direction of the channel width. A diffusion layer is formed to a portion of a substrate situating at a device forming region, thereby forming a source and a drain of a transistor. An insulating layer is formed over the device forming region, over the gate electrode, and over the insulating cover film. A contact is formed to the insulating layer and connected to the diffusion layer. A silicide layer is formed over the gate electrode. A side wall is formed higher than the gate electrode in a region in which the insulating cover film is formed. Then, the contact faces a region of the gate electrode in which the insulating cover film is formed.

### CROSS-REFERENCE TO RELATED APPLICATION

The disclosure of Japanese Patent Application No. 2009-297252 filed on Dec. 28, 2009 including the specification, drawings and abstract is incorporated herein by reference in its entirety.

### BACKGROUND OF THE INVENTION

The present invention concerns a semiconductor device having a field effect transistor and a method of manufacturing the semiconductor device.

Recently, semiconductor devices have been reduced in size and correspondingly, field effect transistors have also been reduced in size.

Japanese Unexamined Patent Publication No. 2003-258257 discloses a semiconductor device having an MISFET (Metal Insulator Semiconductor Field Effect Transistor) formed to an SOI substrate, in which the surface of a gate electrode is covered with an oxide field.

### SUMMARY

As the transistor is reduced in size, a distance between a contact connected to a diffusion region as a source and a drain, and a gate electrode becomes narrow. Accordingly, when a portion of the contact is so close to a side wall as to overlapping the latter caused by mask misalignment or due to necessity in view of layout, insulation breakdown tends to occur between the contact and the gate electrode. On the other hand, for lowering the wiring resistance of the gate electrode, it is also necessary to form a silicide to the gate electrode. That is, for progressing the size-reduction of the transistor, it is necessary to ensure the distance between the contact connected to the diffusion region and the gate electrode while forming the silicide to the gate electrode.

According to an aspect of the present invention, a semiconductor device includes:

a substrate,

a device isolation region formed to the substrate and isolating a device forming region from other regions,

a gate electrode formed to the device forming region,

a side wall covering the side wall of the gate electrode,

an insulating cover film formed over at least a portion of the gate electrode in the direction of the channel width,

a diffusion region formed to the substrate situating at the device forming region and forming a source and a drain,

an insulating layer formed over the device forming region, over the gate electrode, and over the insulating cover film,

a contact formed to the insulating layer and connected to the diffusion layer, and

a silicide layer formed over the gate electrode,

in which the side wall is formed higher than the gate electrode in a region where the insulating cover film is formed, and

the contact faces a region of the gate electrode in which the insulating cover film is formed.

According to the semiconductor device, the contact faces the region of the gate electrode in which the insulating cover film is formed. Then, in the region where the covering insulating layer is formed, the side wall is formed higher than the gate electrode. Therefore, also in a case where a portion of the contact overlaps the side wall caused by mask misalignment or due to the requirement in view of layout, the distance between the contact and the gate electrode is ensured by the side wall. Further, since the insulating cover film is formed only to the portion of the gate electrode, a silicide layer can be formed to a region of the gate electrode in which the insulating cover film is not formed. Accordingly, a distance can be ensured between the contact connected to the diffusion region and the gate electrode while forming a silicide to the gate electrode.

According to another aspect of the invention, a method of manufacturing a semiconductor device includes the steps of:

forming a device isolation region over a substrate thereby isolating a device forming region in which a transistor is formed from other regions,

forming a gate electrode of the transistor in the device forming region,

forming an insulating cover film at least to a portion of the gate electrode in the direction of the channel width,

forming an insulating film over the substrate, over the device isolation region, over the gate electrode, and over the insulating cover film, and forming a side wall by etching back the insulating film,

introducing impurities into a portion of the substrate situating at the device forming region, thereby forming a diffusion region to form a source and a drain of the transistor,

forming a metal film over the gate electrode, and subjecting the metal film and the gate electrode to a heat treatment, thereby forming a silicide layer over the gate electrode,

forming an insulating layer over the transistor, and

forming a contact connected to the diffusion region to the insulating layer,

in which the contact faces a region of the gate electrode covered with the insulating cover film.

According to the invention, a distance can be ensured between the contact connected to the diffusion region and the gate electrode while forming the silicide to the gate electrode.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A and FIG. 1B are cross sectional views showing the constitution of a semiconductor device according to a first embodiment;

FIG. 2 is a plan view of the semiconductor device shown in FIG. 1A and FIG. 1B;

FIG. 3A and FIG. 3B are cross sectional views showing a method of manufacturing the semiconductor device shown in FIG. 1A and FIG. 1B, and FIG. 2;

FIG. 4 is a plan view showing the method of manufacturing the semiconductor device shown in FIG. 1A and FIG. 1B, and FIG. 2;

FIG. 5A and FIG. 5B are cross sectional views showing a method of manufacturing the semiconductor device shown in FIG. 1A and FIG. 1B, and FIG. 2;

FIG. 6 is a plan view showing the method of manufacturing the semiconductor device shown in FIG. 1A and FIG. 1B, and FIG. 2;

FIG. 7A and FIG. 7B are cross sectional views showing a method of manufacturing a semiconductor device shown in FIG. 1 and FIG. 2;

FIG. 8 is a plan view showing the method of manufacturing the semiconductor device shown in FIG. 1A and FIG. 1B, and FIG. 2;

FIG. 9A and FIG. 9B are cross sectional views showing a method of manufacturing the semiconductor device shown in FIG. 1A and FIG. 1B, and FIG. 2;

FIG. 10 is a plan view showing the method of manufacturing the semiconductor device shown in FIG. 1A and FIG. 1B, and FIG. 2;

FIG. 11 is a cross sectional view for explaining the function and the effect of the semiconductor device shown in FIG. 1A and FIG. 1B, and FIG. 2;

FIG. 12 is a cross sectional view for explaining the function and the effect of the semiconductor device shown in FIG. 1A and FIG. 1B, and FIG. 2;

FIG. 13 a cross sectional view for explaining the function and the effect of the semiconductor device shown in FIG. 1A and FIG. 1B, and FIG. 2;

FIG. 14A and FIG. 14B are cross sectional views showing the constitution of a semiconductor device according to a second embodiment;

FIG. 15A and FIG. 15B are cross sectional views showing the method of manufacturing the semiconductor device shown in FIG. 14A and FIG. 14B;

FIG. 16A and FIG. 16B are cross sectional views showing the method of manufacturing the semiconductor device shown in FIG. 14A and FIG. 14B;

FIG. 17A and FIG. 18B are cross sectional views showing the constitution of a semiconductor device according to a third embodiment;

FIG. 18 is a plan view of the semiconductor device shown in FIG. 17A and FIG. 17B;

FIG. 19A and FIG. 19B are cross sectional views showing a method of manufacturing the semiconductor device shown in FIG. 17A and FIG. 17B;

FIG. 20A and FIG. 20B are cross sectional views showing the method of manufacturing the semiconductor device shown in FIG. 17A and FIG. 17B; and

FIG. 21A and FIG. 21B are cross sectional views showing the constitution of a semiconductor device according to a fourth embodiment.

### DETAILED DESCRIPTION OF THE PREFERRED EMBODIMENTS

Preferred embodiments of the invention are to be described with reference to the drawings. Throughout the drawings, identical constituent elements carry the same reference numerals for which explanations are to be omitted optionally.

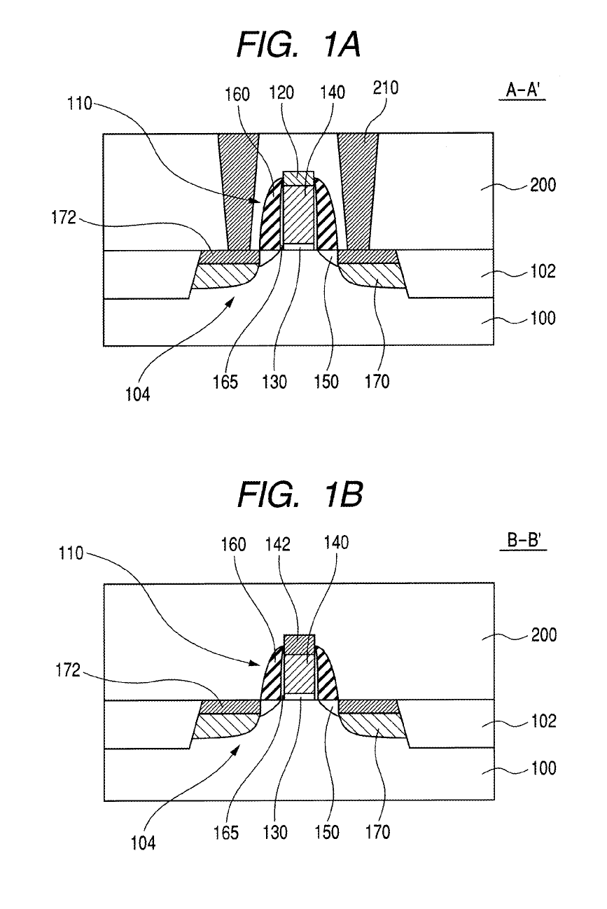

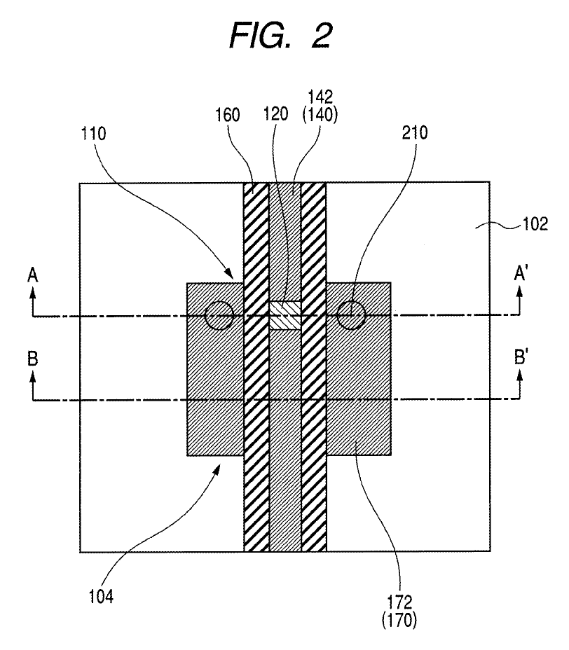

FIG. 1A and FIG. 1B are cross sectional views showing the constitution of a semiconductor device according to a first embodiment, and FIG. 2 is a plan view of the semiconductor device shown in FIG. 1A and FIG. 1B. FIG. 1A is a cross sectional view along A-A in FIG. 2 and FIG. 1B is a cross sectional view along line B-B′ in FIG. 2. The semiconductor device has a substrate 100, a device isolation region 102, a gate electrode 140, a side wall 160, an insulating cover film 120, a diffusion layer 170, and insulating layer 200, a contact 210, and a silicide layer 142. The substrate 100 is, for example, a silicon substrate, which may also be an SOI (Silicon On Insulator) substrate. The device isolation region 102 isolates a device forming region 104 in which a transistor 110 is formed from other regions. The gate electrode 140 is formed in the device forming region 104. The side wall 160 covers the side wall of the gate electrode 140. The insulating cover film 120 is formed at least over a portion of the gate electrode 140 in the direction of the channel width (that is, vertical direction in FIG. 2). The diffusion region 170 is formed to the substrate 100 situating at the device forming region 104 and forms the source and the drain of the transistor 110. The insulating layer 200 is formed over the device forming region 104, over the gate electrode 140, and the insulating cover film 120. The contact 210 is formed to the insulating layer 200 and connected to the diffusion layer 170. The silicide layer 142 is formed over the gate electrode 140. As shown in FIG. 1A and FIG. 1B, the side wall 160 is formed higher than the gate electrode 104 in a region where the insulating cover film 120 is formed. Then, the contact 210 faces a region of the gate electrode 140 in which the insulating cover film 120 is formed. Description is to be made specifically.

In this embodiment, the insulating cover film 120 is formed by leaving a portion of the hard mask used upon forming the gate electrode 140. Then, the insulating cover film 120 is formed over the entire surface of the gate electrode 140 in the direction of the channel length (right to left direction in FIG. 1 and FIG. 2). Further, the silicide layer 142 is not formed to a region of the gate electrode 140 where the insulating cover film 120 situates.

Further, as shown in FIG. 1, the transistor 110 has a gate insulating film 130 and an extension region 150. The gate insulating film 130 situates between a region to form a channel region in the substrate 100 and the gate electrode 140. The extension region 150 is formed in a region of the substrate 100 situating below the side wall 160. A silicide layer 172 is formed to a layer over the diffusion region 170.

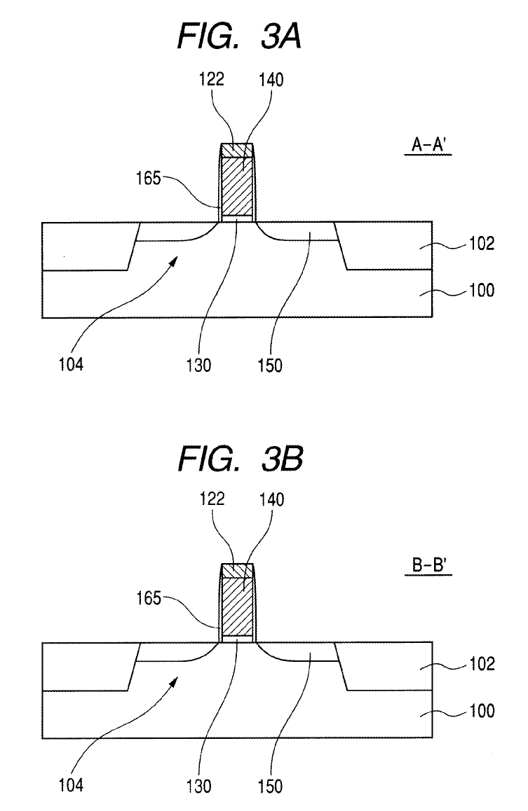

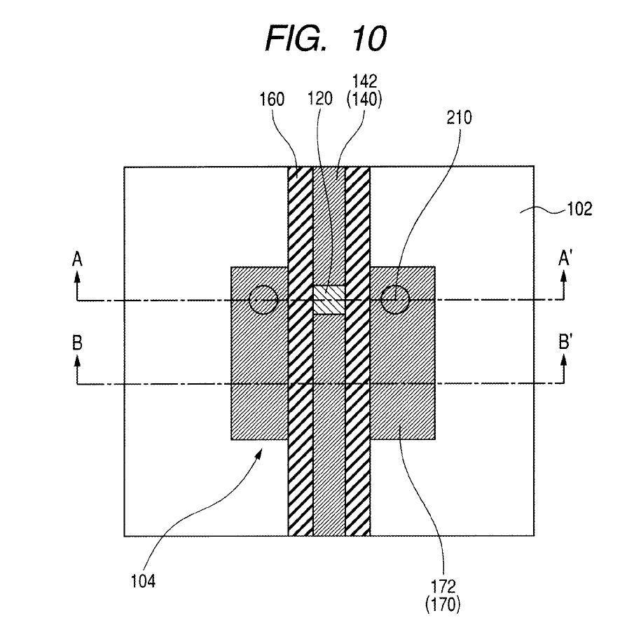

Then, a method of manufacturing the semiconductor device shown in FIG. 1A and FIG. 1B, and FIG. 2 is to be describes with reference to FIG. 3A and FIG. 3B, to FIG. 10. The manufacturing method of the semiconductor device includes the following steps. At first, the device isolation region 102 is formed over the substrate 100 to isolate the device forming region 104 from other regions. Then, the gate electrode 140 of the transistors 110 is formed in the device forming region 104. Then, the insulating cover film 120 is formed to a portion of the gate electrode 140 in the direction of the channel width. Then, an insulating film is formed over the substrate 100, over the device isolation region 102, over the gate electrode 140, and over the insulating cover film 120, and the side wall 160 is formed by etching back the insulating film. Then, impurities are introduced into the portion of the substrate 100 situating at the device forming region 104 to form a diffusion layer 170 of the transistor 110. Then, a metal film is formed over the gate electrode 140, and the metal film and the gate electrode 140 are subjected to a heat treatment to form the silicide layer 142 over the gate electrode. Then, the insulating layer 200 is formed over the transistor 110. Then, the contact 210 is formed to the insulating layer 2. Description is to be made more specifically.

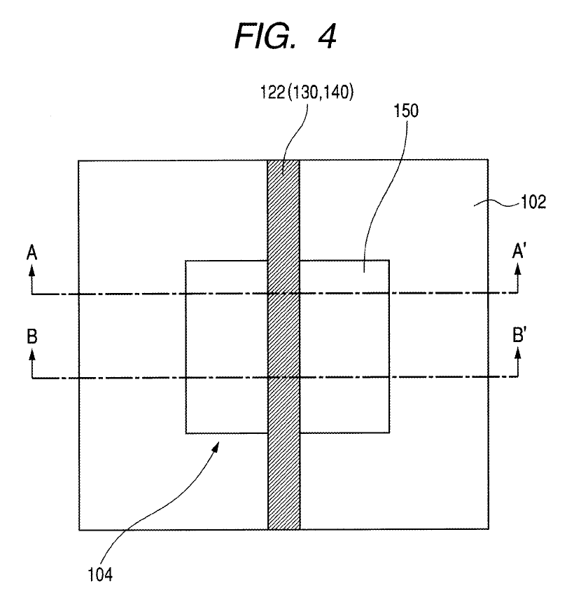

At first, as shown in the cross sectional view along A-A′ in FIG. 3A, the cross sectional view along B-B′ in FIG. 3B, and the plan view of FIG. 4, a trench is formed to the substrate 100, and an insulating film (for example, silicon oxide film) is buried in the trench. Thus, the device isolation region 102 is formed and the device forming region 104 is isolated from other regions. Then, the gate insulating film 130 is formed to a portion of the substrate 100 situating at the device forming region 104. The gate insulating film 130 is a silicon oxide film or a high dielectric constant film having a dielectric constant higher than that of silicon oxide. In the former, the gate insulating film 130 is formed, for example, by a thermal oxidation method and, in the latter, the gate insulative 130 is formed by a deposition method.

Then, a conductive film (for example, polysilicon film) is formed over the gate insulating film 130 and over the device isolation region 102 by a deposition method. Then, an insulating film as a hard mask is formed over the conductive film, and the insulating film is removed selectively. Thus, a hard mask 122 having a predetermined pattern is formed over the conductive film. Then, the conductive film is etched by using the hark mask 122 as a mask. Thus, the conductive film is removed selectively to form the gate electrode 140.

Then, an offset spacer film 165 is formed on the side wall of the gate electrode 140. The thickness of the offset spacer film 165 is, for example, 2 nm or more and 5 nm or less. In this case, the offset spacer film 165 is formed also over the substrate 100 situating over the device isolation region 102 and the device forming region 104 but the offset spacer film 165 formed in such regions may be removed optionally by etching back. Then, impurities are introduced into the substrate 100 using the device isolation region 102, the gate electrode 140, and the offset spacer film 165 as a mask. Thus, the extension region 150 is formed to a portion of the substrate 100 situating at the device forming region 104.

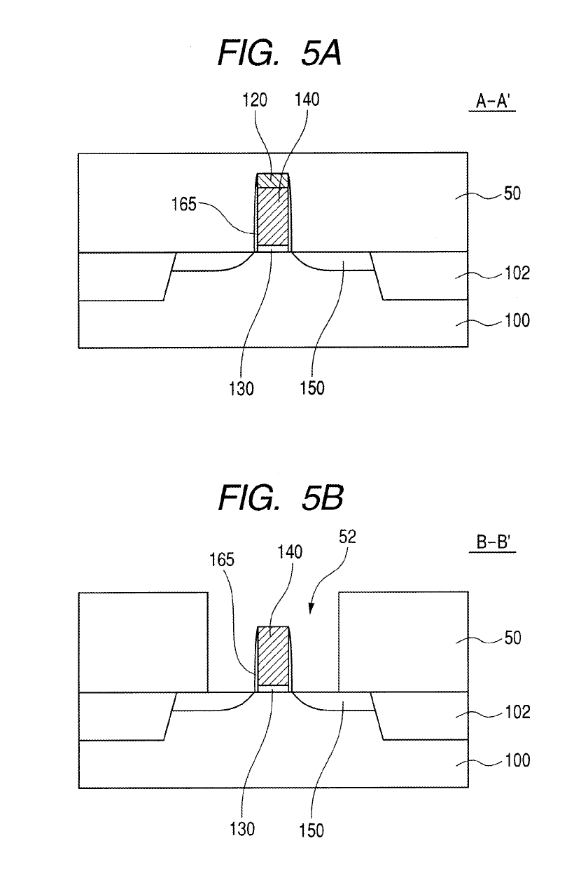

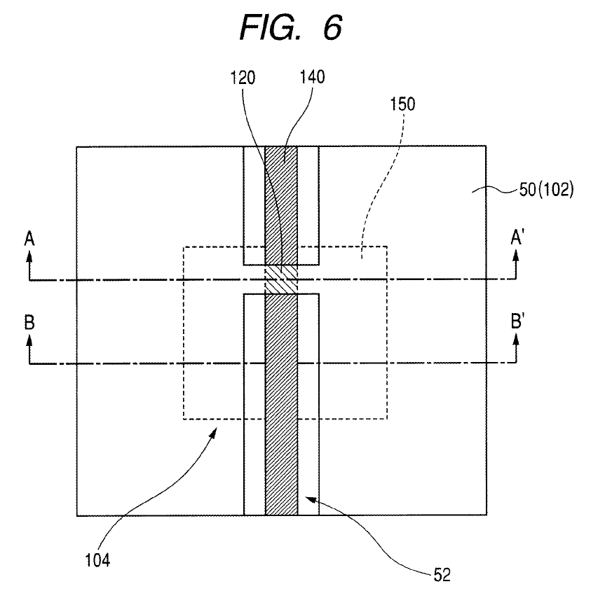

Then, as shown in the cross sectional view along A-A′ in FIG. 5A, the cross sectional view along B-B′ in FIG. 5B, and the plan view of FIG. 6, a resist pattern 50 is formed over the substrate 100. The resist pattern 50 has an opening 52 situating above the gate electrode 140. The opening 52 exposes the gate electrode 140 and the hard mask 122 situating thereover from the resist pattern 50 except for the region facing the contact 210 shown in FIG. 1 and FIG. 2. Then, etching is conducted using the resist pattern 50 as a mask to remove the hard mask 122. Thus, the hard mask 122 is removed except for the region facing the contact 210. Thus, insulating cover film 120 is formed.

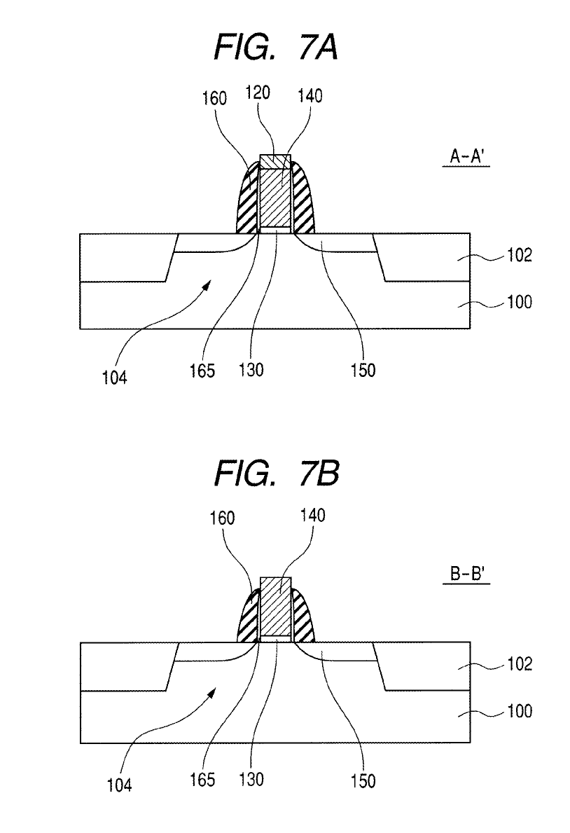

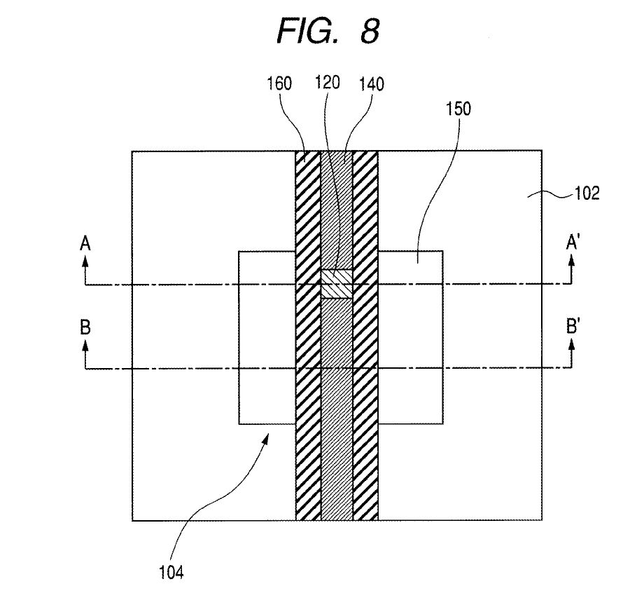

Then, as shown in the cross sectional view along A-A′ in FIG. 7A, the cross sectional view along B-B′ in FIG. 7B, and the plan view of FIG. 8, the resist pattern 50 is removed. Then, an insulating film is formed over the gate electrode 140, over the device isolation film 102, over a portion of the substrate 100 situating at the device forming region 104, and over the offset spacer film 165, and the insulating film is etched back. Thus, the side wall 160 is formed on the side wall of the gate electrode 140. As shown in FIG. 7A, since the insulating cover film 120 is formed to the region of the gate electrode 140 that faces the contact 210, the upper end of the side wall 160 is higher than the upper surface of the gate electrode 140 and situates between the upper surface and the lower surface of the insulating cover film 120. Further, as shown in FIG. 7B, the upper end of the side wall 160 is lower than the upper surface of the gate electrode 140 in a region of the gate electrode 140 not facing the contact 210.

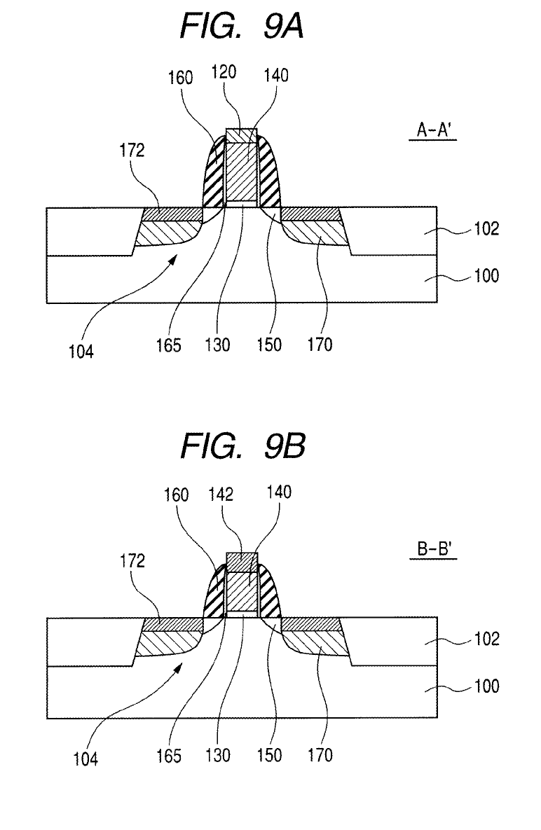

Then, as shown in the cross sectional view along A-A′ in FIG. 9A, the cross sectional view along B-B′ in FIG. 9B, and the plan view of FIG. 10, impurities are introduced into the substrate 100 using the gate electrode 140, the side wall 160, and the device isolation region 102 as a mask. The diffusion region 170 is formed to a portion of the substrate 100 situating at the device forming region 104.

Then, a metal film (for example, Ni) is formed by a sputtering method over the gate electrode 140 and over a portion of the substrate 100 situating at the device forming region 104, and the metal film, the substrate 100, and the gate electrode 140 are subjected to a heat treatment. Thus, the silicide layers 142, 172 are formed. Then, a not-silicided metal film is removed.

Then, as shown in the cross sectional view along A-A′ in FIG. 1A, the cross sectional view along B-B′ in FIG. 1B, and the plan view of FIG. 2, the insulating layer 200 is formed by a CVD method. Then, a via hole is formed in the insulating layer 200 and a conductor (for example, Cu) is buried in the via hole. Thus, the contact 210 is formed to the insulating layer 200.

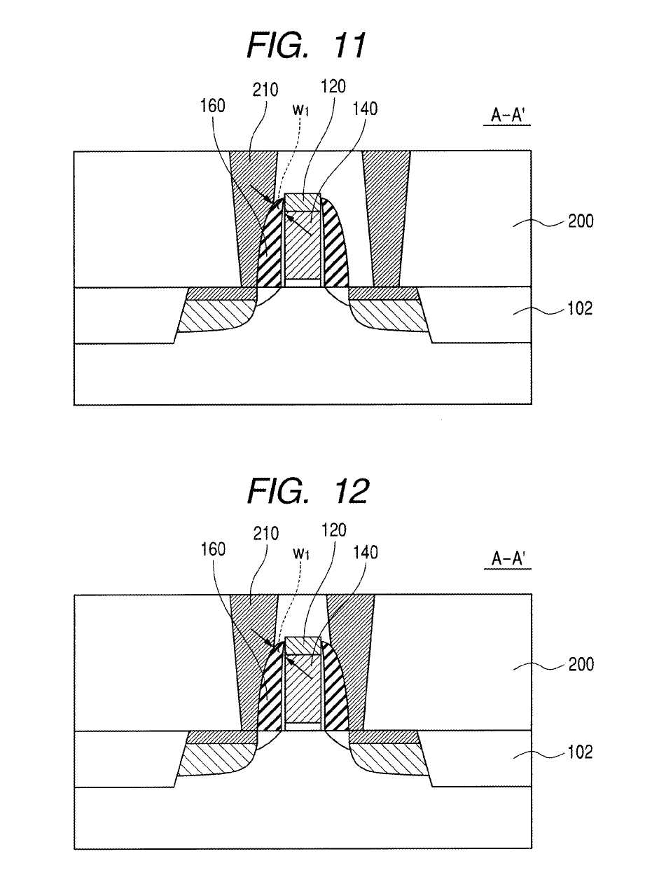

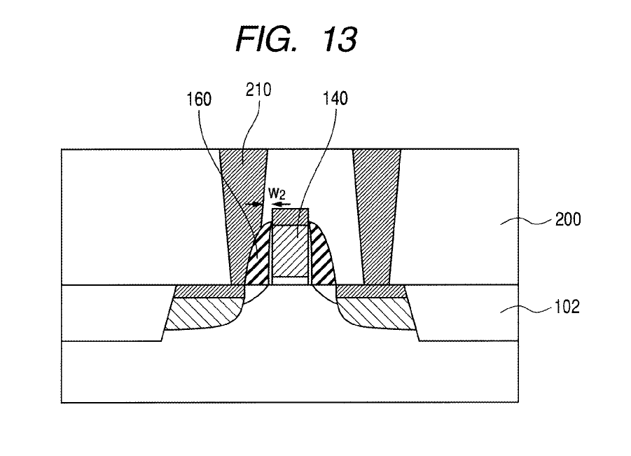

Each of the drawing of FIG. 11, FIG. 12, and FIG. 13 is a cross sectional view for explaining the function and the effect of the semiconductor device shown in FIG. 1A and FIG. 1B, and FIG. 2. As shown in FIG. 11, when the via hole is formed in the insulating layer 200, mask misalignment may sometimes occur in which the contact 210 overlaps the side wall 160. Further, when the size reduction of the semiconductor device is progressed, it may be a case where a portion of the contact 210 has to be overlapped with the side wall 160 as shown in FIG. 12. In these cases, when the insulating cover film 120 is not formed as shown in FIG. 13, since the upper end of the lateral surface of the gate electrode 140 is not covered with the side wall 160, the shortest distance between the contact 210 and the gate electrode 140 is a distance w2 between the upper end of the lateral surface of the gate electrode 140 and a portion of the lateral surface of the contact 210 at a height identical with the upper end of the gate electrode 140. On the contrary, when the insulating cover film 120 is formed as shown in FIG. 11 and FIG. 12, the upper end of the lateral surface of the gate electrode 140 is covered with the side wall 160. Accordingly, the distance between the upper end of the lateral surface of the gate electrode 140 and a portion of the lateral surface of the contact 210 at a height identical with the upper end of the gate electrode 140 is widened compared with the example shown in FIG. 13. Accordingly, the shortest distance w1 between the contact 210 and the gate electrode 140 is wider than w2 in the case of FIG. 13. Therefore, a distance between the contact connected to the diffusion region and the gate electrode can be ensured.

Further, the insulating cover film 120 is formed only in the region of the gate electrode 140 facing the contact 210. Accordingly, the silicide layer 142 is formed in the region of the gate electrode 140 not facing the contact 210. Therefore, the interconnection resistance of the gate electrode 140 can be lowered.

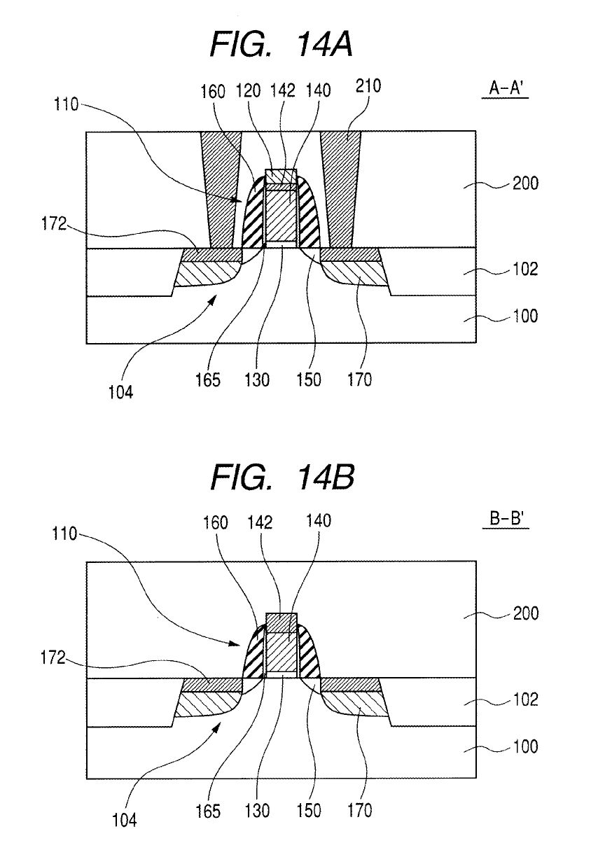

Each of the drawings of FIG. 14A and FIG. 14B is a cross sectional view showing the constitution of a semiconductor device according to a second embodiment. FIG. 14A corresponds to a cross sectional view along A-A′ in FIG. 2, and FIG. 14B corresponds to a cross sectional view along B-B′ in FIG. 2. The semiconductor device has an identical constitution with that of the first embodiment excepting that the silicide layer 142 is formed also to a region of the gate electrode 140 that is covered by the insulating cover film 120. That is, in this embodiment, the silicide layer 142 is formed substantially over the entire surface of the gate electrode 140. However, the thickness of the silicide layer 142 situating below the insulating cover film 120 is less than that of the silicide layer 142 situating at other regions.

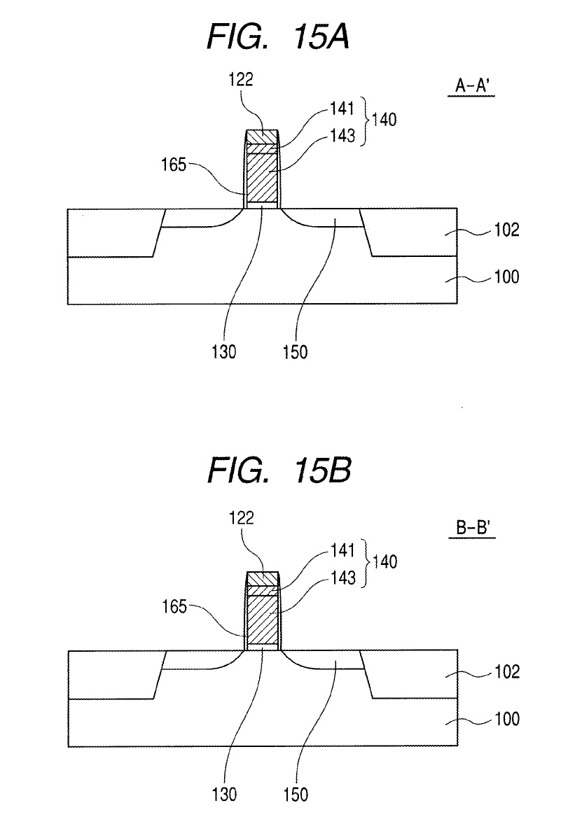

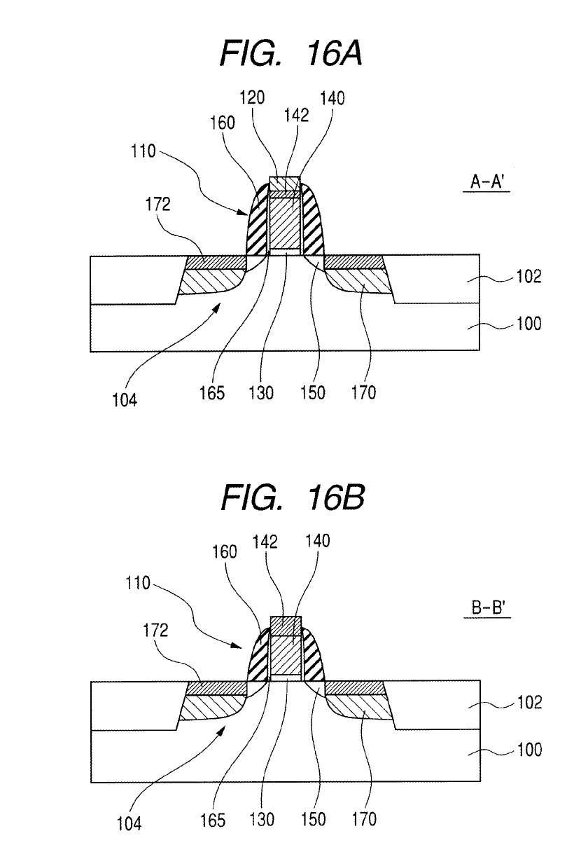

FIG. 15A and FIG. 15B and FIG. 16 are cross sectional vies showing the method of manufacturing the semiconductor device shown in FIG. 14A and FIG. 14B. At first, as shown in a cross sectional view along A-A′ in FIG. 15A and a cross sectional view along B-B′ in FIG. 15B, a device isolation region 102 and a gate insulating film 130 are formed to a substrate 100. The method of forming them is identical with that in the first embodiment.

Then, a polysilicon layer and a silicon containing film are formed in this order over the device isolation region 102 and over the substrate 100. The silicon containing film is a film in which silicide reaction species are thermally diffused more and silicided more than the polysilicon layer, for example, a porous silicon film or, an SiC film, or a second polysilicon layer deposited at a lower temperature than that for the polysilicon layer described above. Then, a hard mask 122 is formed over the silicon containing film, and the silicon containing film and the polysilicon layer are etched by using the hard mask 122 as a mask. The gate electrode 140 is formed as described above. The gate electrode 140 has a stacked structure in which the polysilicon layer 143 and the silicon containing film 141 are stacked in this order.

Then, an offset spacer film 165 and an extension region 150 are formed. The method of forming them is identical with that in the first embodiment.

Then, as shown in a cross sectional view along A-A′ in FIG. 16A and a cross sectional view along B-B′ in FIG. 16B, a side wall 160, a diffusion region 170, and silicide layers 142, 172 are formed. The method of forming the side wall 160, the diffusion region 170, and the silicide layers 142, 172 is identical with that in the first embodiment. However, the upper layer of the gate electrode 140 is formed of the silicon containing film 141 as described above. The silicon containing film 141 is silicided more easily than the polysilicon layer 143. Therefore, the silicon containing film 141 situating below the insulating cover film 120 is also silicided and, as a result, the silicide layer 142 is formed also below the insulating cover film 120.

Subsequently, as shown in the cross sectional view along A-A′ in FIG. 14A and the cross sectional view along B-B′ in FIG. 14B, the insulating layer 200 and the contact 210 are formed. The method of forming them is identical with that in the first embodiment.

Also in to this embodiment, the same effect as that of the first embodiment can be obtained. Further, since the silicide layer 142 is formed substantially over the entire surface of the gate electrode 140, the resistance of the gate electrode 140 can be lowered further.

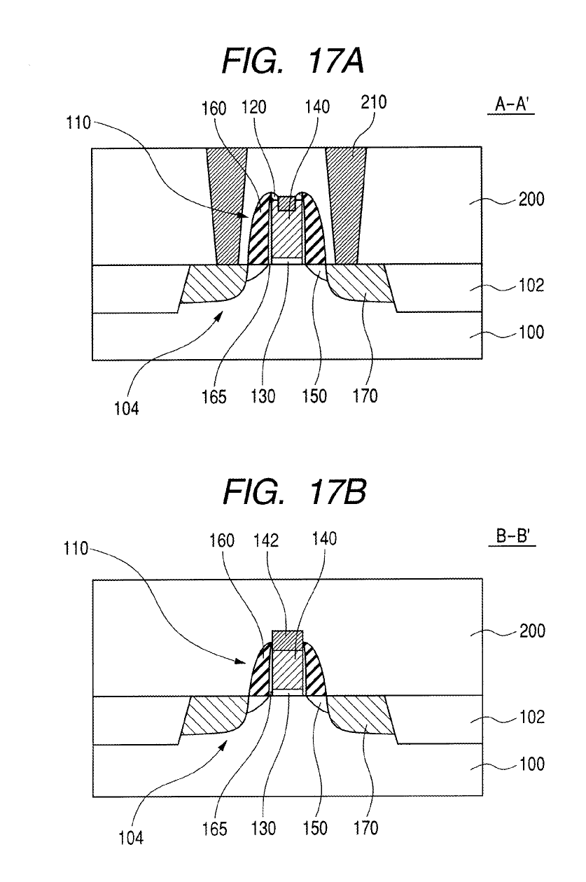

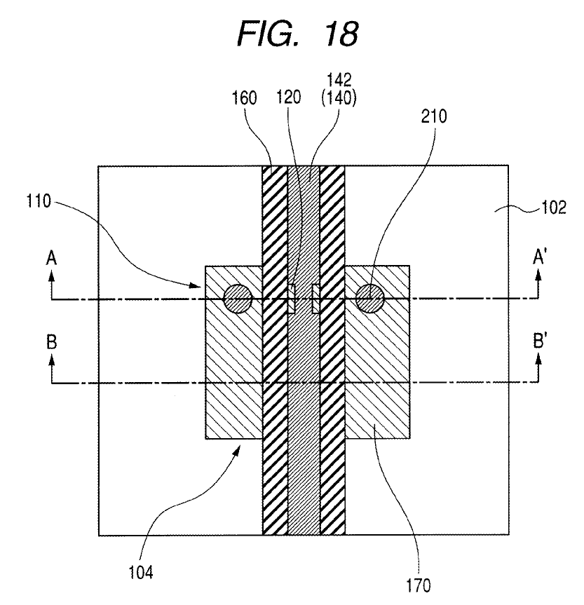

Each of the drawings of FIG. 17A and FIG. 17B is a cross sectional view showing the constitution of a semiconductor device according to a third embodiment and FIG. 18 is a plan view of the semiconductor device shown in FIG. 17A and FIG. 17B, FIG. 17A corresponds to a cross sectional view along A-A′ in FIG. 18 and FIG. 17B corresponds to a cross sectional view along B-B′ in FIG. 18. The semiconductor device has the same constitution as that of the semiconductor device according to the first embodiment excepting that the insulating cover film 120 is not formed in the central portion in the longitudinal direction of the channel, and the silicide layer 142 is formed also in the central portion. That is, the insulating cover film 120 has a shape of the side wall in this embodiment.

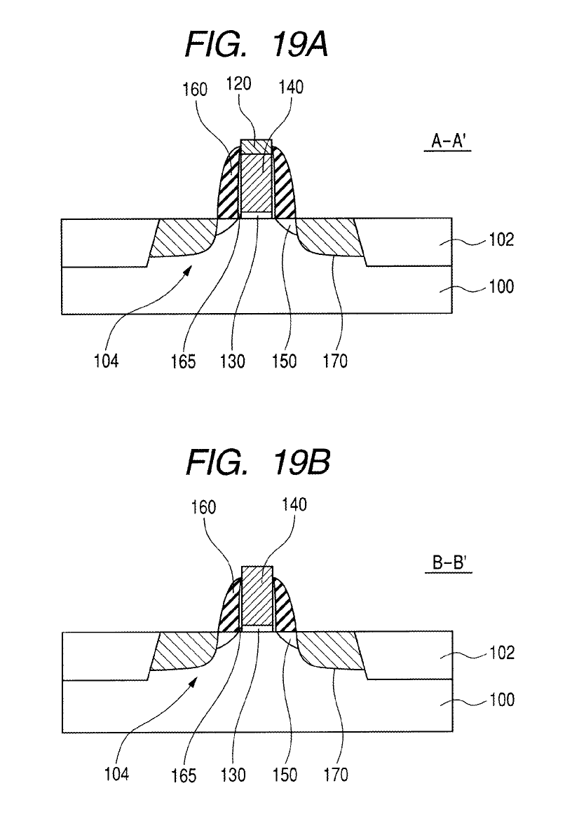

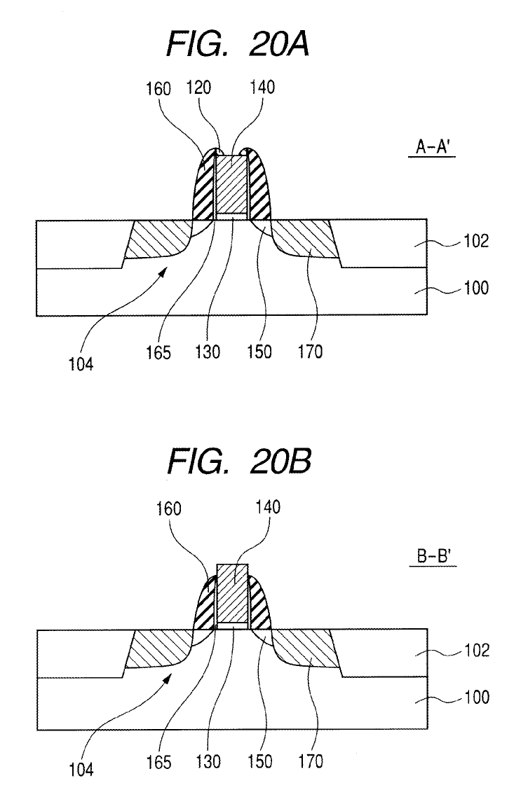

Each of the drawings of FIG. 19A and FIG. 19B, and FIG. 20A and FIG. 20B is a cross sectional view showing a method of manufacturing the semiconductor device according to this embodiment. At first, as shown in the cross sectional view along A-A′ of FIG. 19A and the cross sectional view along B-B′ of FIG. 19B, a device isolation region 102, a gate insulating film 130, a gate electrode 140, an offset spacer film 165, an extension region 150, an insulating cover film 120, a side wall 160, and a diffusion region 170 are formed to the substrate 100. The method of forming them is identical with that in the first embodiment.

Then, as shown in the cross sectional view along A-A′ of FIG. 20A and the cross sectional view along B-B′ of FIG. 20B, the insulating cover film 120 is etched back. Thus, the insulating cover film 120 is removed from the central portion in the direction of the channel length.

Subsequently, a metal film is formed by a sputtering method over the gate electrode 140 and over a portion of the substrate 100 situating at the device forming region 104, and the metal film, the substrate 100, and the gate electrode 140 are subjected to a heat treatment. Thus, the silicide layers 142, 172 are formed. The insulating cover film 120 is removed from the central portion in a direction of the channel length in the region of the gate electrode 140 facing the contact 210. Therefore, when viewed in the direction of the channel width, the silicide layer 142 is continuously formed with no discontinuity over the gate electrode 140. Then, a not-silicided metal film is removed.

Then, as shown in the cross sectional view along A-A′ of FIG. 17A and the cross sectional view along B-B′ of FIG. 17B, the insulating layer 200 and the contact 210 are formed. The method of forming them is identical with that in the first embodiment.

Also according to this embodiment, the same effect as that in the first embodiment can be obtained. Further, when viewed in the direction of the channel width, the silicide layer 142 is continuously formed with no discontinuity over the gate electrode 140. Accordingly, the resistance of the gate electrode 140 can be lowered further.

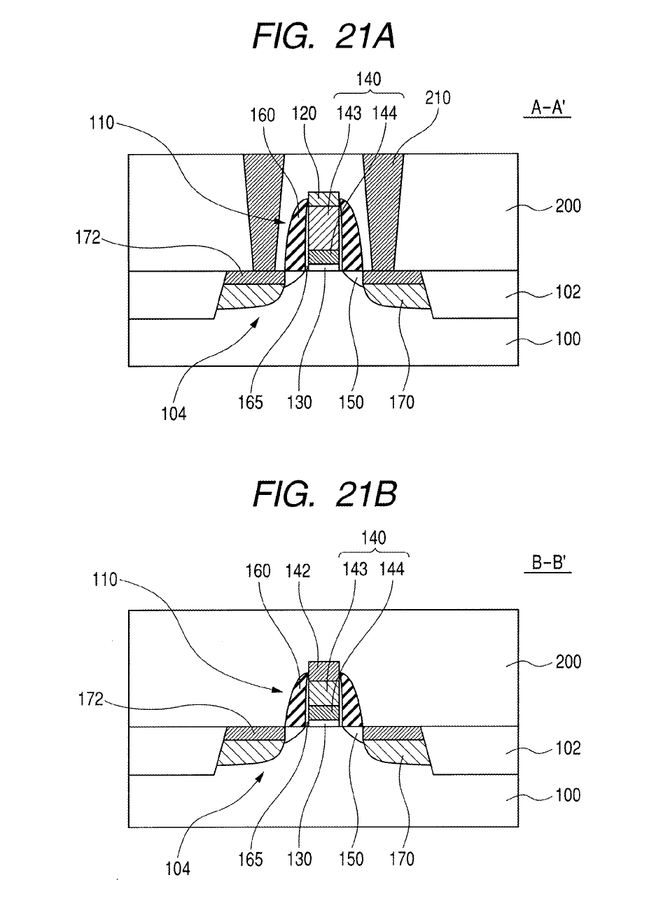

FIG. 21 is a cross sectional view showing a constitution of a semiconductor device according to a fourth embodiment. The semiconductor device has the same constitution as that of the semiconductor devices according to the first to third embodiments except for the following points.

At first, the gate insulating film 130 is formed of a high dielectric constant film. Further, the gate electrode 140 has a structure in which the metal layer 144 and the polysilicon layer 143 are stacked in this order.

The method of manufacturing the semiconductor device is identical with the manufacturing method of the semiconductor devices shown in the first to the third embodiments excepting that the conductive layer to constitute the gate electrode 140 is formed as a stacked structure of the metal layer and the polysilicon layer.

Also according to this embodiment, the same effect as that in the first to the third embodiments can be obtained.

While the present invention has been described for the preferred embodiments with reference to the drawings, this is only the examples of the invention and various other constitutions than those described above can also be adopted.

It should be noted that the method claims according to the present invention may be summarized as follows:

(7) A method of manufacturing a semiconductor device comprising:

forming a device isolation region over a substrate thereby isolating a device forming region in which a transistor is formed from other regions;

forming a gate electrode of the transistor in the device forming region;

forming an insulating cover film at least to a portion of the gate electrode in the direction of the channel width;

forming an insulating film over the substrate, over the device isolation region, over the gate electrode, and over the insulating cover film, and forming a side wall by etching back the insulating film;

introducing impurities into a portion of the substrate situating at the device forming region, thereby forming a diffusion region to form a source and a drain of the transistor;

forming a metal film over the gate electrode, and subjecting the metal film and the gate electrode to a heat treatment, thereby forming a silicide layer over the gate electrode;

forming an insulating layer over the transistor; and

forming a contact connected to the diffusion region to the insulating layer,

wherein the contact faces the region of the gate electrode covered with the insulating cover film.

(8) The semiconductor device manufacturing method according to claim 7, wherein the step of forming the gate electrode includes:

forming a conductive film to form a gate electrode of the transistor over the device isolation region and over the substrate;

forming a hard mask over the conductive film; and

etching the conductive film by using the hard mask as a mask, thereby forming the gate electrode,

wherein the forming the insulating cover film is forming the insulating cover film by using the hard mask and removing a portion of the hard mask.

(9) The semiconductor device manufacturing method according to claim 7, wherein the step of forming the gate electrode includes:

forming a silicon layer;

forming a silicon containing film which is silicided more easily than the silicon layer over the silicon layer; and

selectively removing the silicon layer and the silicon containing film, thereby forming the gate electrode.

(10) The semiconductor device manufacturing method according to claim 9,

wherein the silicon containing film comprises a porous silicon film, an SiC film, or a second silicon layer deposited at a temperature lower than that for the silicon layer.

(11) The semiconductor device manufacturing method according to claim 7, further comprising:

etching back the insulating cover film after the forming the side wall and before the forming the silicide layer, thereby removing the insulating cover film from the central portion in the direction of the channel length.

What is claimed is:

1. A semiconductor device comprising:
a substrate;
a device isolation region formed to the substrate and separating a device forming region from other regions;
a gate electrode formed in the device forming region;
a side wall covering the side wall of the gate electrode;
an insulating cover film formed at least over a portion of the gate electrode in the direction of a channel width;
a diffusion region formed to a portion of the substrate situating at the device forming region and forming a source and a drain;
an insulating layer formed over the device forming region, over the gate electrode, and over the insulating cover film;
a contact formed to the insulating layer and connected to the diffusion region; and
a silicide layer formed over the gate electrode,
wherein the side wall is formed higher than the gate electrode in a region where the insulating cover film is formed, and
wherein the contact faces a region of the gate electrode in which the insulating cover film is formed.

2. The semiconductor device according to claim 1,
wherein a portion of the contact overlaps with the side wall as viewed in a plane.

3. The semiconductor device according to claim 1,
wherein the insulating cover film is formed over the entire surface of the gate electrode in the direction of a channel length.

4. The semiconductor device according to claim 1,
wherein the silicide layer is formed except for a region of the gate electrode in which the insulating cover film is situated.

5. The semiconductor device according to claim 4,
wherein the insulating cover film is not formed to a central portion in the direction of the channel length.

6. The semiconductor device according to claim 1,
wherein the silicide layer is formed substantially over the entire surface of the gate electrode.
